(19) United States
(12) Patent Application Publication
(10) Pub. No.: US 2024/0087888 A1
(43) Pub. Date: Mar. 14, 2024

(54) METHOD OF FORMING A SI-COMPRISING EPITAXIAL LAYER SELECTIVELY ON A SUBSTRATE

(71) Applicant: ASM IP Holding, B.V., Almere (NL)

(72) Inventor: Rami Khazaka, Leuven (BE)

(21) Appl. No.: 18/465,835

(22) Filed: Sep. 12, 2023

Related U.S. Application Data
(60) Provisional application No. 63/375,615, filed on Sep. 14, 2022.

(51) Int. Cl. H01L 21/02; C30B 25/10; H01L 21/3065

(52) U.S. Cl. CPC H01L 21/02532; C30B 25/10; H01L 21/02381; H01L 21/02433; H01L 21/02579; H01L 21/0262; H01L 21/3065

(57) ABSTRACT

A method for forming a Si-comprising epitaxial layer selectively on a substrate is disclosed. Embodiments of the presently described method comprise performing a cyclic deposition and etch processes, thereby forming selectively the Si-comprising epitaxial layer. The described method may help to form source/drain regions of field effect transistors in a bottom-up manner.

### CROSS-REFERENCE TO RELATED APPLICATION(S)

This Application claims the benefit of U.S. Provisional Application 63/375,615 filed on Sep. 14, 2022, the entire contents of which are incorporated herein by reference.

### FIELD OF INVENTION

The present disclosure relates to a method and a substrate processing apparatus for forming epitaxial layers on a substrate. More specifically, the disclosure relates to a method and a substrate processing apparatus for forming a Si-comprising epitaxial layer on a substrate.

### BACKGROUND OF THE DISCLOSURE

With advancing Complementary Metal Oxide Semiconductor (CMOS) technology in semiconductor industry in an effort to keep up with scaling, new device architectures have come into play such as for example fin-type field effect transistors (FinFET), gate-all-around (GAA) type field effect transistors. Furthermore, improvements in semiconductor process technology have become inevitable in order to provide the desired performance for such devices.

One of the challenges faced long with the process technology improvements may involve enabling epitaxial growth at lower temperatures. This may aid in the enablement of integration schemes such as for example, monolithic integration, buried power rails, high-k/metal gate first integration and source/drain contact formation.

Among these schemes, providing a higher dopant concentration and a reduced contact resistivity may play a major role particularly in enabling future source/drain formations with reduced resistance in line with the new architectures coming into play in an effort to improve device performance.

Therefore, there may be a need for improving formation of source/drain regions in semiconductor devices.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter

It may be an object of the present disclosure to improve formation of source/drain regions in semiconductor devices.

In a first aspect, the present disclosure relates to a method for forming a Si-comprising epitaxial layer selectively on a substrate. The method may comprise providing a substrate to a process chamber. The substrate may comprise an exposed surface. The exposed surface may comprise a first exposed surface and a second exposed surface, the second exposed surface may be different than the first exposed surface. The method may further comprise providing, to the process chamber, a Si-containing precursor, thereby forming a Si-comprising epitaxial layer on the exposed surface. The epitaxial layer may comprise a first portion formed on the first exposed surface and a second portion formed on the second exposed surface. The method may further comprise providing an etching gas to the process chamber, thereby removing, selectively, the first portion or the second portion of the epitaxial layer. The Si-containing precursor may be a silicon halide precursor comprising at least one of iodine and bromine.

The method according to embodiments of the first aspect of the present disclosure may allow for forming a Si-comprising epitaxial layer selectively on the substrate.

It may be an advantage of embodiments of the first aspect that the Si-comprising epitaxial layer may be formed selectively on the substrate at a lower process temperature. This may help to keep up with scaling efforts in semiconductor industry, whereby a reduced temperature budget may be maintained.

It may be an advantage of embodiments of the first aspect that the Si-comprising epitaxial layer may be formed selectively on the substrate at a lower process temperature while maintaining a higher growth rate. This may allow for improving process throughput.

It may be an advantage of embodiments of the first aspect that the Si-comprising epitaxial layer may maintain a higher active dopant concentration. This may enable improving performance of contacts formed such as for example source/drain contacts, thereby providing a reduced contact resistance.

It may further be an advantage of embodiments of the first aspect that the Si-comprising layer may present a reduced layer resistivity. This may enable improving performance of contacts formed such as for example source/drain contacts, thereby providing a reduced contact resistance.

It may further be an advantage of embodiments of the first aspect that a bottom-up epitaxial layer formation may be enabled. This may allow for a defect-poor layer formation. This may further be advantageous for improving source/drain formation.

It may be an advantage of embodiments of the first aspect allowing for enabling source/drain formation of GAA devices.

It may be an advantage of embodiments of the first aspect allowing for enabling via formation for buried power rails.

In a second aspect, the present disclosure relates to a substrate processing apparatus for forming a Si-comprising layer selectively on a substrate. The apparatus may comprise a process chamber constructed and arranged for holding a substrate. The apparatus may also comprise a silicon precursor storage module that may comprise di-chlorosilane and a silicon halide precursor. The silicon halide precursor may comprise at least one of iodine and bromine. The apparatus may further comprise a germanium precursor storage module that may comprise germane. A heater may be comprised in the apparatus that may be configured for heating and maintaining process temperature in the process chamber and a pressure controller that may be configured for attaining and maintaining process pressure in the process chamber. The apparatus may further comprise a controller that may be operably connected to the silicon precursor storage module and to the germanium precursor storage module and may be configured for executing instructions that may be comprised in a non-transitory computer readable medium and may cause the substrate processing apparatus to form the epitaxial layer on the substrate in accordance with a method according to embodiments of the first aspect.

The substrate processing apparatus according to embodiments of the second aspect of the present disclosure may allow for the formation of a Si-comprising epitaxial layer selectively on the substrate.

It may be an advantage of embodiments of the second aspect that the substrate processing apparatus may allow for selective formation of a Si-comprising layer having a higher active dopant concentration and with improved resistivity.

It may be an advantage of embodiments of the second aspect that the substrate processing apparatus may contribute to improving overall semiconductor processing throughput thanks to the improved growth rates.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

Like reference numbers will be used for like elements in the drawings unless stated otherwise. Reference signs in the claims shall not be understood as limiting the scope.

FIG. 1: A flowchart of an exemplary method according to embodiments of the first aspect of the present disclosure.

FIG. 2(a) to FIG. 2(c): A schematic representation of an exemplary method according to embodiments of the first aspect of the present disclosure.

FIG. 3: X ray reflectivity curves (XRR) on different substrate surfaces (SiO₂, Si(001) and Si(110)

FIG. 4: Thickness vs. etch duration for SiGe:B layer.

FIG. 5: Omega 2-theta scan around the (004) X-ray diffraction order of SiGe:B layer on top of Si(001)

FIG. 6(a) and FIG. 6(b): SiGe:B layer thickness by co-flowing DCS as a function of SiI₂H₂ flow rate; FIG. 6(a) thickness grown vs. SiI₂H₂ precursor flow rate and FIG. 6(b) etched thickness vs. SiI₂H₂ precursor flow rate.

FIG. 7(a) and FIG. 7(b): Change of resistivity of SiGe:B layer as a function of FIG. 7(a) SiI₂H₂ precursor flow rate and FIG. 7(b) B₂H₆ flow rate.

FIG. 8: Etched thickness of SiGe:B layer vs. B₂H₆ flow rate as a function of SiI₂H₂ flow rate.

FIG. 9(a) to FIG. 9(c): A schematic representation of a gap comprised in the substrate.

FIG. 10: A schematic representation of a substrate processing apparatus according to embodiments of the second aspect of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-_limiting examples of a continuous substrate may include a sheet, a roll, a foil, provided that the continuous substrate consists of monocrystalline material. Continuous substrates may also comprise carriers or sheets upon which non-continuous substrates are mounted.

It is to be noticed that the term “comprising”, as used herein, should not be interpreted as being restricted to the means listed thereafter. It does not exclude other elements or steps. Thus, it does not prevent one or more other steps, components, or features, or groups thereof from being present or being added. It is to be interpreted as specifying the presence of the stated features, steps or components as referred to.

Reference throughout the specification to “some embodiments” means that a particular structure, feature step described in connection with these embodiments is included in some of the embodiments of the present invention. Thus, phrases appearing such as “in some embodiments” in different places throughout the specification are not necessarily referring to the same collection of embodiments, but may.

Reference throughout the specification to “embodiments” in various places are not necessarily all referring to the same embodiment, but may. Furthermore, the particular features, structures or characteristics may be combined in any suitable manner, as would be apparent to one of the ordinary skill in the art from the disclosure, in one or more embodiments.

It is to be noticed that the term “comprise substantially” used in the claims refers that further components than those specifically mentioned can, but not necessarily have to, be present, namely those not materially affecting the essential characteristics of the material, compound, or composition referred to.

The following terms are provided solely to help in the understanding of the disclosure.

As used herein and unless provided otherwise, the term “substantially simultaneously” may refer to may refer to the silicon-halide precursor and the process gas being provided to the process chamber, to a great extent, during overlapping time durations.

As used herein and unless provided otherwise, the term “blanket layer” may refer to a layer of a film disclosing no features on the surface.

As used herein and unless provided otherwise, the term “bottom-up filling” may refer to a growth of an film, whereby the growth starts from a bottom of a feature and goes in a vertical direction extending away from the bottom surface. The feature may be a gap.

As used herein and unless provided otherwise, the term “gap” may refer to a pattern that is recessed in the substrate or within a layer that is comprised in the substrate.

As used herein and unless provided otherwise, the term “gate all around FET” may refer to a FET device where the gate material surrounds the channel region on all sides. The channel of the may be in the form of a nanosheet or a nanowire.

The disclosure will now be described by a detailed description of several embodiments of the disclosure. It is clear that other embodiments of the disclosure can be configured according to the knowledge of persons skilled in the art in the absence of departure from the technical teaching of the disclosure. The disclosure is limited only by the terms of the claims included herein.

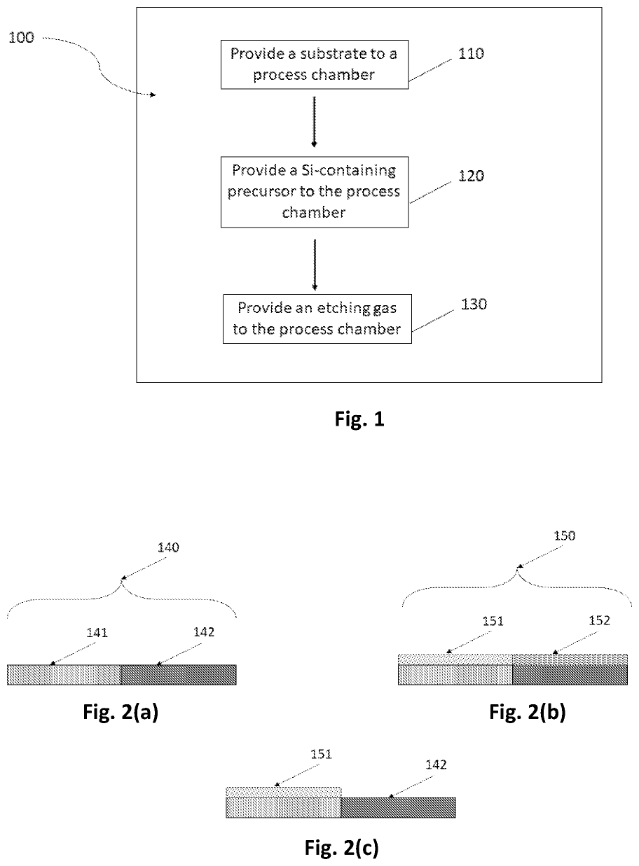

Referring to the figures now, FIG. 1 is a flowchart and FIGS. 2(a) to 2(c) are schematic representations of an exemplary method according to embodiments of the first aspect of the present disclosure.

The method (100) may be suitable for forming a Si-comprising epitaxial layer selectively on a substrate. The method (100) may comprise providing a substrate to a process chamber (110). The substrate may comprise an exposed surface (140) for forming the Si-comprising epitaxial layer (150). The exposed surface may comprise a first exposed surface (141) and a second exposed surface (142). The second exposed surface (142) may be different from the first exposed surface (141) (FIG. 2(a)).

A Si-containing precursor may be provided (120) to the process chamber, thereby forming a Si-comprising epitaxial layer (150) on the exposed surface (140). The epitaxial layer (150) may comprise a first portion (151) formed on the first exposed surface (141) and a second portion (152) formed on the second exposed surface (142) (FIG. 2(b)).

The difference between the first exposed surface (141) and the second exposed surface (142) may allow for forming the Si-comprising epitaxial layer selectively on one of the two exposed surfaces (141, 142)

The Si-containing precursor may be a Si halide precursor comprising at least one of iodine and bromine.

In embodiments, the silicon halide precursor may be a halo-silane having a formula of SiHₙX₄₋ₙ, where X may be a halogen including F, Cl, Br and I, and n varies from 1 to 5.

In some embodiments, the silicon halide precursor may be a iodosilane following a general a formula SiₙI_{y}A_{z}H_{2n+2-y-z}

wherein n=1-10, y=1 or more (and up to 2n+2−z), z=0 or more (and up to 2n+2−y), and A is a halogen other than I, preferably n=1-5 and more preferably n=1-3 and most preferably 1-2.

In some embodiments, the iodosilane may be a cyclic iodosilane having a general formula SiₙI_{y}A_{z}H_{2n-y-z}

wherein n=3-10, y=1 or more (and up to 2n-z), z=0 or more (and up to 2n-y), and A is a halogen other than I, preferably n=3-6.

In some embodiments, the silicon halide precursor may be a bromo silane having a general formula SiₙBr_{y}A_{z}H_{2n+2-y-z}

wherein n=1-10, y=1 or more (and up to 2n+2−z), z=0 or more (and up to 2n+2−y), and A is a halogen other than Br, preferably n=1-5 and more preferably n=1-3 and most preferably 1-2.

In some embodiments, the bromo silane may be a cyclic bromo silane having a general formula SiₙBr_{y}A_{z}H_{2n-y-z}

wherein n=3-10, y=1 or more (and up to 2n−z), z=0 or more (and up to 2n−y), and A is a halogen other than Br, preferably n=3-6.

In some embodiments, the silicon halide precursor may be a iodosilane following a general a formula SiₙI_{y}H_{2n+2-y}

wherein n=1-5, y=1 or more (and up to 2n+2−y), preferably n=1-3 and more preferably n=1-2.

In some embodiments, the iodosilane may be SiHI₃, SiH₂I₂, SiH₃I, HSi₂I₅, H₂Si₂I₄, H₃Si₂I₃, H₄Si₂I₂, H₅Si₂I or combinations thereof.

In certain embodiments, the iodosilane may be SiH₂I₂

In some embodiments, the silicon halide precursor may be a bromo silane having a general formula SiₙBr_{y}H_{2n+2-y}

wherein n=1-5, y=1 or more (and up to 2n+2−y), preferably n=1-3 and more preferably n=1-2.

In some embodiments, the bromo silane may be SiHBr₃, SiH₂Br₂, SiH₃Br, HSi₂Br₅, H₂Si₂Br₄, H₃Si₂br₃, H₄Si₂Br₂, H₅Si₂Br or combinations thereof.

In certain embodiments, the bromo silane may be SiH₂Br₂

In some embodiments, the first exposed surface (141) and the second exposed surface (142) may both be monocrystalline while each exposed surface may have a different crystal orientation from one another. This may lead to a difference in growth rate of the Si-comprising epitaxial layer (150) as a function of the difference in crystal orientation, thereby leading to selectivity in growth.

In some embodiments, the difference between the first exposed surface (141) and the second exposed surface (142) may be such that the first exposed surface (141) and the second exposed surface (142) may have different crystallinity.

Thus, in some embodiments, the first exposed surface (141) may be monocrystalline while the second exposed surface (142) may be non-monocrystalline, while in some embodiments the first exposed surface (141) may be non-monocrystalline while the second exposed surface (142) may be monocrystalline.

In some embodiments, the non-monocrystalline surface may be a polycrystalline surface or an amorphous surface. The growth of the Si-comprising layer (150) may thus, be favored on the monocrystalline surface compared to the polycrystalline or amorphous surface, thus leading to selectivity in growth. This may originate from the difference in growth rate occurring between the polycrystalline or amorphous surface and the Si-comprising layer (150) thus, hindering growth on the non-monocrystalline surface. Furthermore, nucleation delay during the growth of the epitaxial layer may play a role thereby, retarding the growth on the polycrystalline or amorphous surface.

An etching gas may be provided (130) to the process chamber. This may selectively remove the first portion (151) or the second portion (152) of the epitaxial layer (150). As schematically exemplified in in FIG. 2(c), in some embodiments, the etching gas may remove the second portion (152) of the epitaxial layer (150), thereby exposing the second surface (142), while the first portion (151) still remains. It is to be noted that a surface of the first portion (151) of the epitaxial layer (151) may also be etched upon exposure to the etching gas. However, compared to the etch rate of the second portion (152) of the epitaxial layer (150), etch rate of the first portion may be smaller thereby, not influencing the integrity of the first portion (151) of the epitaxial layer (150).

In embodiments, the etching gas may comprise an etchant selected from the group consisting of chlorine (Cl₂) and bromine (Br₂). In embodiments, the etchant gas may be provided in the presence of a carrier gas.

In embodiments, the carrier gas may comprise N₂, and noble gases such as for example, Ar, Ne, He, Xe and Kr.

In some embodiments, the carrier gas may comprise substantially N₂, Ar, He, or combinations thereof.

In embodiments, the provision of the Si-containing precursor (120) and the provision of the etching gas (130) may be repeated in a cyclic manner, thus, leading to a cyclic deposition and etch (CDE) process. This may allow for an increase in the thickness of the Si-comprising epitaxial layer (151) formed on the first exposed surface as schematically represented in FIG. 2(c).

In embodiments, the first exposed surface (141) and the second exposed surface (142) may be of the same material or may comprise the same material.

In embodiments, the first exposed surface (141) and the second exposed surface (142) may be of silicon or may comprise silicon.

In some embodiments, the first exposed surface (141) may comprise a Si {100}facet and the second exposed surface (142) may comprise a non-monocrystalline layer. The non-monocrystalline layer may be polycrystalline or amorphous. In some embodiments, the second exposed surface (142) may comprise silicon oxide. In these embodiments, the first portion (151) of the Si-comprising layer (150) may be monocrystalline and the second portion (152) of the Si-comprising epitaxial layer (150) may be polycrystalline or amorphous. The second exposed surface (142) may further comprise a high order Si facet. In embodiments, the second surface may further comprise germanium or silicon germanium. The high order Si facet may be a Si {110} facet. In some embodiments, the second exposed surface (142) may further comprise monocrystalline silicon.

In some embodiments, the first exposed surface (141) may consist of a Si {100}facet and the second exposed surface may consist of silicon oxide. In these embodiments, the first portion (151) of the Si-comprising layer (150) may be monocrystalline and the second portion (152) of the Si-comprising epitaxial layer (150) may be polycrystalline or amorphous.

In some embodiments, the first exposed surface (141) may comprise silicon oxide and the second exposed surface may comprise either a Si {100} facet or a high order Si crystal facet.

In some embodiments, the first exposed surface (141) may consist of silicon oxide and the second exposed surface (142) may consist of a high order Si crystal facet, where the high order Si crystal facet may for example be Si{110} facet. In these embodiments, the first portion (151) of the Si-comprising layer (150) may be polycrystalline or amorphous and the second portion (152) of the Si-comprising epitaxial layer (150) may be monocrystalline.

In some embodiments, the first exposed surface (141) may comprise a Si {100}facet and the second exposed surface may consist of a high order Si crystal facet.

In some embodiments, the first exposed surface (141) may consist of a Si {100}crystal facet and the second exposed surface (142) may consist of a Si {110} crystal facet.

In these embodiments, both the first portion (151) and the second portion (152) of the Si-comprising epitaxial layer (150) may be mono-crystalline. However, the growth rate may change depending on the crystal facet. Thus, when the etching gas is provided to the process chamber, the portion of the Si-comprising epitaxial layer (150) having a lower thickness may be etched faster than the portion of the Si-comprising epitaxial layer (150) having a higher thickness, thereby, leading eventually to selective epitaxial growth of the Si-comprising epitaxial layer, such as exemplified in FIG. 2(c). Furthermore, etch rate of the second portion (152) of the Si-comprising epitaxial layer (150), such as for example the portion formed on the second exposed surface (142) and consisting of the Si {110} crystal facet, may be higher than the first portion (151) of the Si-comprising epitaxial layer (150), such as for example the portion formed on the first exposed surface (141) and consisting the Si {100} crystal facet thereby, allowing for the removal the second portion (152) of the epitaxial layer.

For selective epitaxial growth of Si-comprising layer, where one of the exposed surfaces comprises a silicon oxide and the other exposed surface comprises a Si {100) facet or a high order silicon facet, the portion of the Si-comprising epitaxial layer may be polycrystalline or amorphous on the exposed silicon oxide surface, while the portion of the Si-comprising epitaxial layer may be mono-crystalline on the exposed surface comprising the Si {100) facet or the high order silicon facet.

In embodiments, the silicon halide precursor may be provided, to the process chamber, substantially simultaneously with a process gas comprising at least a Ge-containing precursor and a p-type dopant precursor, thereby, forming a p-type doped SiGe epitaxial layer. The p-type doped SiGe epitaxial layer (150) may be formed on the first exposed surface (141) and on the second exposed surface (142).

In embodiments, the p-type dopant precursor may comprise diborane, thereby leading to the presence of boron dopant in the epitaxial SiGe layer grown (150) that may be denoted as SiGe:B.

In some embodiments, the p-type dopant precursor may be diborane, B₂H₆.

The provision of the p-type dopant precursor, particularly the provision of boron being the p-type dopant, may play an important role in the selective epitaxial growth of the SiGe layer. It may advantageously lead to a reduction in the sheet resistance of the layer grown on one hand and on the other hand, it may maintain a higher growth rate of the epitaxial SiGe layer.

Furthermore, substitutional incorporation of the p-type dopant may also lead to obtaining an epitaxial layer with a lower sheet resistance thereby, advantageously allowing for enhanced growth of the layer as source/drain regions of semiconductor devices, whereby the enablement of higher growth rate may help to improve throughput of the epitaxial growth process.

In these embodiments, p-type doped SiGe epitaxial layer (150) may be monocrystalline and the growth rate of the p-type doped SiGe epitaxial layer may change depending on the exposed surface in case both the first exposed surface (141) and the second exposed surface (142) are both monocrystalline but having a different crystal facet.

In these embodiments, where one of the exposed surfaces comprises a silicon oxide, such as for example the first exposed surface (141), and the other exposed surface comprises a Si {100} facet or a high order Si crystal facet, such as for example the second exposed surface (142), then the portion of the p-type doped SiGe epitaxial layer (151) may be polycrystalline or amorphous on the first exposed surface (141) and the portion (152) may be monocrystalline on the second exposed surface (142).

In embodiments, the p-type dopant precursor may be provided to the process chamber in the presence of a carrier gas.

In embodiments, the Ge-containing precursor may be a mono-germane or a high order germane.

In embodiments, the p-type dopant precursor is diborane and the Ge-containing precursor is germane. The combination of diborane and germane may offer easy process integration in terms of epitaxial layer as these precursors are easily available.

In embodiments, the Ge-containing precursor may be provided to the process chamber in the presence of a carrier gas.

In embodiments, the silicon halide precursor may be provided to the process chamber in the presence of a carrier gas.

In embodiments, the process chamber may be maintained, during the selective formation of the epitaxial layer (150), at a temperature less than 450° C. and at a pressure in a range of 10 Torr to 80 Torr.

In embodiments, these process parameters in terms of temperature and pressure may be maintained during the selective epitaxial formation of the p-type doped SiGe layer.

In embodiments, the process temperature may be between 250° C. and 450° C.

In some embodiments, the process temperature may be from at least 250° C. to at most 275° C., or from at least 275° C. to at most 300° C. or from at least 300° C. to at most 325° C., or from at least 325° C. to at most 350° C., or from at least 350° C. to at most 375° C., or from at least 375° C. to at most 400° C., or from at least 400° C. to at most 425° C., or from at least 425° C. to at most 450° C.

In some embodiments, the process temperature may be about 400° C.

In embodiments, process temperature may be measured using a thermocouples. The process temperature referred to in the present disclosure may be measured by using a thermocouple that may be placed centrally beneath the susceptor comprised in the semiconductor processing apparatus for forming the Si-comprising epitaxial layer, where the substrate rests on the susceptor.

In some embodiments, the process pressure may be from at least 10 Torr to at most 20 Torr, or from at least 20 Torr to at most 30 Torr, or from at least 30 Torr to at most 40 Torr, or from at least 40 Torr to at most 50 Torr, or from at least 50 Torr to at most 60 Torr, or from at least 60 Torr to at most 70 Torr, or from at least 70 Torr to at most 80 Torr.

In embodiments, the silicon halide precursor may be provided into the process chamber at a flow rate in a range of 50 sccm to 1000 sccm.

In some embodiments, the silicon halide precursor may be provided to the process chamber at a flow rate from at least 50 sccm to at most 100 sccm, or from at least 100 sccm to at most 150 sccm, or from at least 150 sccm to at most 200 sccm, or from at least 200 sccm to at most 250 sccm, or from at least 250 sccm to at most 300 sccm, or from at least 300 sccm to at most 350 sccm, or from at least 350 sccm to at most 400 sccm, or from at least 400 sccm to at most 450 sccm, or from at least 450 sccm to at most 500 sccm, or from at least 500 sccm to at most 550 sccm, or from at least 550 sccm to at most 600 sccm, or from at least 600 sccm to at most 650 sccm, or from at least 650 sccm to at most 700 sccm, or from at least 700 sccm to at most 750 sccm, or from at least 750 sccm to at most 800 sccm, or from at least 800 sccm to at most 850 sccm, or from at least 850 sccm to at most 900 sccm, or from at least 900 sccm to at most 950 sccm, or from at least 950 sccm to at most 1000 sccm. It is to be understood that the flow rates given herein may be provided for a 300 mm wafer being the substrate and a reaction chamber having a volume of 1 L. The skilled person can readily convert these flow rate values to other substrate sizes and to other reaction chamber volumes.

In some embodiments, the silicon halide precursor may be provided to the process chamber at a flow rate of 800 sccm. The silicon halide precursor comprising iodine or bromine, such as for example SiI₂H₂ or SiBr₂H₂, are in liquid form. In order to provide it to the process chamber the silicon halide precursor may be provided to a bubbler and H₂ may be used to bubble the liquid precursor in the bubbler. A mixture of H₂ gas and the precursor in vapor form leaves the bubbler. With the help of a carrier gas further on, the mixture of H₂ gas and the precursor vapor may be transferred to the process chamber. When the temperature of the vessel holding the liquid precursor is kept a temperature in a range of 15° C. to 40° C. then the flow rate of 800 sccm may be a desirable flow rate value for its provision to the process chamber.

In embodiments, the Ge-containing precursor may be provided to the process chamber at a flow rate in a range of 100 sccm to 800 sccm.

In some embodiments, the Ge-containing precursor may be provided to the process chamber at flow rate from at least 100 sccm to at most 200 sccm, or from at least 200 sccm to at most 300 sccm, or from at least 300 sccm to at most 400 sccm, or from at least 400 sccm to at most 500 sccm, or from at least 500 sccm to at most 600 sccm, or from at least 600 sccm to at most 700 sccm, or from at least 700 sccm to at most 800 sccm.

In embodiments, the p-type dopant precursor may be provided to the process chamber at a flow rate in a range of 1 sccm to 150 sccm.

In some embodiments, the p-type dopant precursor may be provided to the process chamber at a flow rate from at least 1 sccm to at most 10 sccm, or from at least 10 sccm to at most 20 sccm, or from at least 20 sccm to at most 30 sccm, or from at least 30 sccm to at most 40 sccm, or from at least 40 sccm to at most 50 sccm, or from at least 50 sccm to at most 60 sccm, or from at least 60 sccm to at most 70 sccm, or from at least 70 sccm to at most 80 sccm, from at least 80 sccm to at most 90 sccm, or from at least 90 sccm to at most 100 sccm, or from at least 100 sccm to at most 110 sccm, or from at least 110 sccm to at most 120 sccm, or from at least 120 sccm to at most 130 sccm, or from at least 130 sccm to at most 140 sccm, or from at least 140 sccm to at most 150 sccm.

In embodiments, the process gas may comprise substantially of the Ge-containing precursor and the p-type dopant precursor. This may be in combination with the silicon halide precursor being provided to the process chamber substantially simultaneously with the process gas. This may thus, advantageously enable the selective formation of the SiGe:B epitaxial layer, whereby number of precursors is reduced. This may allow for reducing process costs and also may allow for performing a simpler epitaxial process

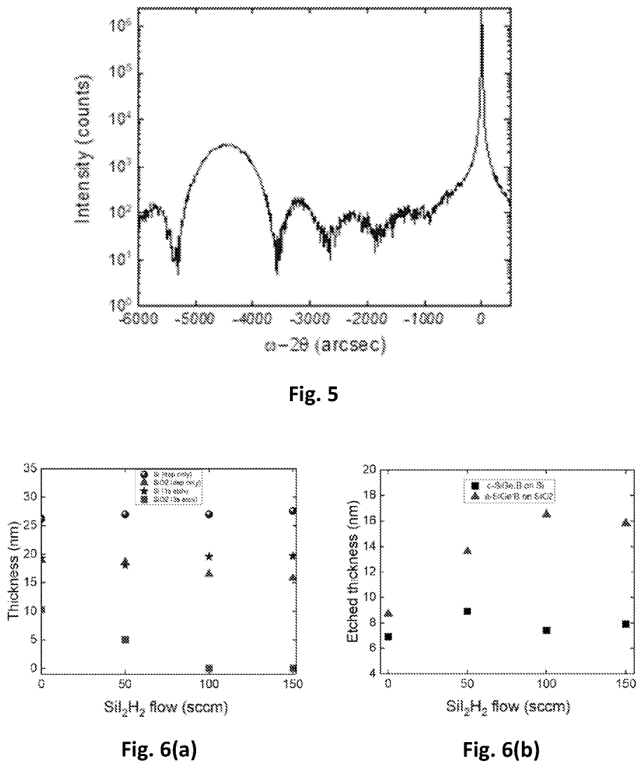

The epitaxial SiGe:B layer formed may advantageously be a high quality layer that allows for growth at a temperature lower than 450° C. By high quality layer it may be meant to have good crystal quality and a low surface roughness value. It is to be noted that high quality layer within the context of epitaxial growth disclosed in the present disclosure may relate to the epitaxial layer having substantially no defects, no threading dislocations and substantially being strain relaxation-free. Furthermore, the presence of fringes as seen in, for example, FIG. 5 is an indication of a high quality layer. It is also to be noted that a low surface value may infer that the epitaxial layer may have an RMS value of less than 0.2 nm measured by Atomic Force Microscopy (AFM) at a scan area of 2×2 micrometer square.

In embodiments, where the process gas may comprise substantially of the Ge-containing precursor, the process temperature may be maintained at a temperature of about 400° C. and at a pressure of about 20 Torr. Additionally, in these embodiments, the p-type dopant may be provided at a flowrate in a range of 1 sccm to 3 sccm

In some embodiments, the p-type dopant may be provided at a flowrate of about 2 sccm.

In some embodiments, the silicon halide precursor may be provided to the process chamber at a flow rate of about 800 sccm.

In embodiments where the process gas comprises substantially of the Ge-containing precursor and the p-type dopant precursor, then the Ge-containing precursor may be provided to the process chamber at a flow rate in a range of 100 sccm to 400 sccm.

In some embodiments, the flow rate of the Ge-containing precursor may be 200 sccm.

It is to be understood that the flow rate of the Ge-containing precursor may be tuned depending on the amount of atomic percentage of Ge desired in the final SiGe:B epitaxial layer.

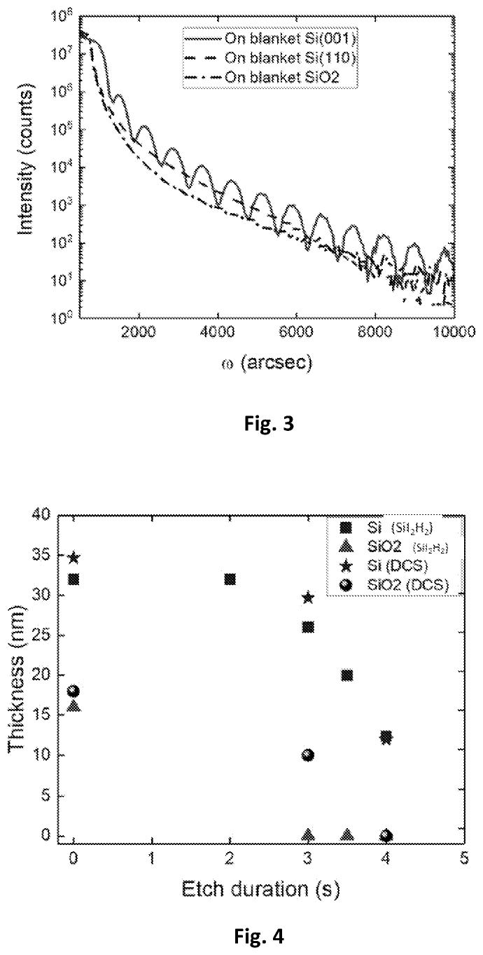

We now turn to FIG. 3, FIG. 4 and FIG. 5, whereby blanket SiGe:B epitaxial layer is formed when the process gas comprises substantially of the Ge-containing precursor and the p-type dopant precursor and the silicon-halide precursor is provided substantially simultaneously with the process gas to the process chamber.

We now turn to FIG. 3 showing X-Ray reflectivity curves of an epitaxially grown boron-doped silicon germanium (SiGe:B) layer on blanket silicon oxide and on monocrystalline silicon surfaces, the monocrystalline Si surface being a Si (001) surface and a Si (110) surface.

It is observed from FIG. 3 that growth of SiGe:B epitaxial layer is selective towards blanket silicon oxide layer. The presence of fringes observed on Si (001) surface is an indication that the SiGe:B epitaxial layer is selectively grown on Si (001) surface. This may be due to the difference in density between the substrate and the layer grown on top of it. On the other hand, absence of fringes may indicate absence of a layer grown on Si (110) and SiO₂ surface.

It is further observed that growth on a Si (110) surface and on SiO₂ is quite limited as judged from FIG. 3. The absence of fringes in the XRR reflectivity curves regarding the epitaxial layer grown on the Si (110) surface and on SiO₂ is an indication of substantially no growth of the epitaxial layer.

This may thus, provide the advantage of growth of SiGe:B epitaxial layer selectively on a Si (001) surface in comparison to growth on a Si (110) surface or in comparison to growth on a surface of silicon oxide.

FIG. 4 shows a graph of thickness of the blanket SiGe:B epitaxial layer grown as a function of the etch duration. The graph also presents a comparison when the growth of the blanket SiGe:B epitaxial layer is done by using SiI₂H₂ precursor vs. SiCl₂H₂ precursor and on a silicon oxide layer vs. on Si (001) layer. By etch duration it is meant the total time of exposure of the blanket SiGe:B epitaxial layer to the etching gas.

It selectivity in terms of etching of the blanket SiGe:B epitaxial layer grown on a Si (001) surface in comparison to the blanket SiGe:B epitaxial layer grown on silicon oxide surface is observed by the fast decay in the thickness of the layer as etch duration is increased for the two types of precursors used in the growth.

It is furthermore observed that use of SiI₂H₂ as the Si-containing precursor for the growth of the blanket SiGe:B epitaxial layer instead of SiCl₂H₂ provides further the advantage of enhanced etch selectivity of the layer grown on the silicon oxide surface with respect to the layer grown on Si (001) surface. It is of particular advantage, for example that a higher etch rate thus, provision of a faster etch selectivity is obtained, when the layer is grown using SiI₂H₂ as the Si-containing precursor is used, already after 3 seconds into the etching process. This may advantageously provide improvement on process throughput as the duration of etching process may in this way be reduced while still enabling selectivity.

FIG. 5 shows Omega 2-theta scan around the (004) X-ray diffraction order of SiGe:B layer on top of Si(001) surface.

The germanium content in the SiGe:B layer is 47.5% atomic.

The resistivity of the SiGe:B layer is measured to be about 0.17 mOhm·cm. Having such a lower value may advantageously provide the use of such layers for source/drain formation. As feature sizes are further scaling down and new device architectures are being implemented, reduction in particularly source/drain contact resistance becomes an important element for the performance of devices. Provision of source/drain layers having reduced resistivity values may thus, advantageously allow for keeping up with scaling in semiconductor industry.

Additionally, the formation of such lower resistivity epitaxial SiGe:B layers, further contributes to the enablement of new device architectures as they can be grown at lower temperatures, such as for example 400° C., thus offering a lower temperature budget for the integration scheme.

In embodiments, the process gas may further comprise a chlorosilane precursor. Thus, in embodiments, the silicon halide precursor may be provided substantially simultaneously with the process gas that may further comprise the chlorosilane precursor. In embodiments, the chlorosilane precursor may be di-chlorosilane (DCS) or tri-chlorosilane (TCS). This may advantageously provide enhancement in the etching of the SiGe:B layer formed on the silicon oxide surface, which is amorphous, compared to the monocrystalline SiGe:B epitaxial layer formed on the monocrystalline Si surface, thereby contributing to the selectivity of the growth process.

In embodiments, when the process gas further comprises a chlorosilane precursor during the selective formation of the epitaxial SiGe:B layer, the process chamber may be maintained at a temperature in a range of 250° C. to 300° C. and at a pressure in a range of 10 Torr to 60 Torr, when the process gas further comprises the chlorosilane precursor.

In some embodiments, the process temperature may be from at least 250° C. to at most 260° C., or from at least 260° C. to at most 270° C., or from at least 270° C. to at most 280° C., or from at least 280° C. to at most 290° C., or from at least 290° C. to at most 300° C.

In some embodiments, the pressure maintained in the process chamber when the silicon halide precursor is provided substantially simultaneously with the process gas that may further comprise the chlorosilane precursor may be from at least 10 Torr to at most 20 Torr, or from at least 20 Torr to at most 30 Torr, or from at least 30 Torr to at most 40 Torr, or from at least 40 Torr to at most 50 Torr, or from at least 50 Torr to at most 60 Torr.

In embodiments, the chlorosilane precursor may be dichlorosilane (DCS).

In embodiments when the process gas may further comprise a chlorosilane precursor, the flow rate of the Ge-containing precursor may be in a range of 400 sccm to 500 sccm. It is to be noted that in cases where a higher atomic percentage of germanium is preferred in the epitaxial layer, then the flow rate of the Ge-containing precursor may be increased above 500 sccm.

FIG. 6(a) shows a graph of change of thickness of selective epitaxial SiGe:B layer formed as a function of SiI₂H₂ precursor flow rate when the process gas further comprises di-chlorosilane and SiI₂H₂ precursor is provided, to the process chamber, substantially simultaneously with the process gas. The process temperature is in a range between 250° C. and 400° C., whereby the flow rate of germane flow is in a range between 200 sccm to 1000 sccm and flow rate of SiI₂H₂ precursor is in a range between 0 sccm to 600 sccm.

It is observed from this figure that the thickness of the epitaxial SiGe:B layer formed on the Si surface after deposition, the Si surface being Si(001), is higher compared to thickness of the layer formed on the silicon oxide surface, silicon oxide being SiO₂. This indicates that the growth rate of the SiGe:B epitaxial layer is higher on Si(001) surface compared to that on the SiO₂ surface and may be an indication of selective growth on the Si surface.

Furthermore, the graph shows the change of thickness of the SiGe:B epitaxial layer on the Si surface and on the silicon oxide surface, as a function of SiI₂H₂ precursor flow rate after when the layer is exposed to the etching gas, the etch exposure time being set to 3 seconds. It is observed that while the thickness of the epitaxial layer on the Si surface remains fairly constant over increasing flow rate of SiI₂H₂ precursor, the thickness of the layer on silicon oxide layer shows a decrease as a function of the SiI₂H₂ precursor flow rate increases, when subjected to the etching gas. This shows that the presence of SiI₂H₂ precursor helps to get the amorphous SiGe:B layer formed on silicon oxide to get etched faster and without significant impact on the etch rate of monocrystalline SiGe:B layer formed on Si(001). This advantageously helps to obtain selective deposition of the SiGe:B epitaxial layer.

FIG. 6(b) shows a graph of etched thickness as a function of SiI₂H₂ precursor flow rate, when the SiGe:B layer is subjected to the etching gas. SiGe:B layer formed on the Si surface is monocrystalline and that on silicon oxide surface is amorphous. It is observed from this figure that upon exposure to the etching gas, SiGe:B epitaxial layer formed on silicon oxide is etched faster. Etching time is taken to be 3 seconds in these experiments.

In some embodiments, the process temperature may be maintained at about 270° C. This may provide the advantage of increased p-type dopant concentration into the SiGe epitaxial film, the p-type dopant being boron. This may have to do with the fact that typically at higher temperatures for epitaxial growth, higher temperatures being above 450° C., there may be limitations relating to active dopant incorporation into the epitaxial layer. Furthermore, the total dopant that will be present in the epitaxial layer may be limited prior to loosing crystallinity. Therefore, process temperature that may be maintained around 270° C. may advantageously improve active p-type dopant incorporation. Active dopant concentration in the epitaxial layer may be measured by using a Hall effect measurement set-up as known to persons skilled in the art.

In embodiments, when the process gas further comprises the chlorosilane precursor, the flow rate of the Ge-containing precursor may be in a range of 300 sccm to 700 sccm.

In some embodiments, the flow rate of the Ge-containing precursor may be from at least 300 sccm to at most 350 sccm, or from at least 350 sccm to at most 400 sccm, or from at least 400 sccm to at most 450 sccm, or from at least 450 sccm to at most 500 sccm, or from at least 500 sccm to at most 550 sccm, or from at least 550 sccm to at most 600 sccm, or from at least 600 sccm to at most 650 sccm, or from at least 650 sccm to at most 700 sccm.

In some embodiments, the flow rate of the Ge-containing precursor may be 400 sccm. This may advantageously contribute to obtaining an epitaxial SiGe:B layer with reduced resistivity and absence of or reduced strain relaxation in the layer.

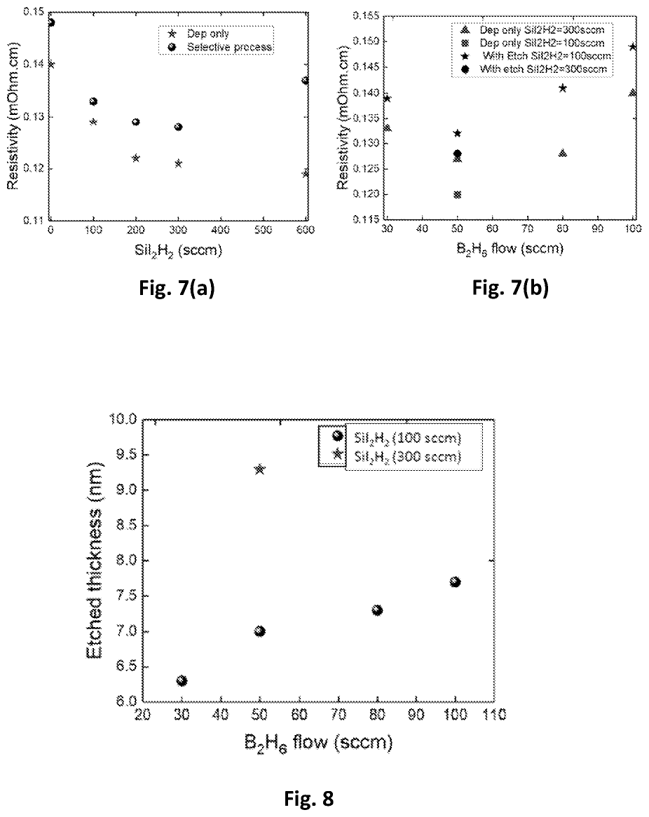

We now return to FIG. 7(a) showing change of resistivity of Si-containing layer (SiGe:B) as a function of Si halide precursor flow (SiI₂H₂). In these experiments, temperature of the process is maintained at about 270° C. and the process gas further comprises di-chlorosilane. The epitaxial growth is done on a Si (001) surface.

It is observed in FIG. 7(a) that as the flow rate of SiI₂H₂ precursor is increased resistivity of the epitaxial layer shows initially a decrease both for the deposition only case and for the selective case. In the deposition only case, selectivity is not achieved as deposition of the epitaxial layer takes place also on the oxide surface, being SiO₂. In the selective deposition process, selective growth of the SiGe:B epitaxial layer is achieved on the Si(001) surface. At a flowrate of 600 sccm an increase is observed in the resistivity of the epitaxial SiGe:B layer.

In embodiments, when the process gas further comprises the chlorosilane precursor, the p-type dopant precursor may be provided at a flow rate in a range of 25 sccm to 200 sccm. This may provide the advantage of enabling the tuning of the resistivity, growth rate of the epitaxial layer and the dopant activation of the SiGe:B epitaxial film.

In some embodiments, the flow rate of the p-type dopant precursor, when the process gas further comprises the chlorosilane precursor, may be from at least 25 sccm to at most 50 sccm, or from at least 50 sccm to at most 70 sccm, or from at least 70 sccm to at most 90 sccm, or from at least 90 sccm to at most 110 sccm, or from at least 110 sccm to at most 130 sccm, or from at least 130 sccm to at most 150 sccm, or from at least 150 sccm to at most 170 sccm, or from at least 170 sccm to at most 200 sccm.

In some embodiments, the flow rate of the p-type dopant precursor may be set to 100 sccm. This may advantageously allow for obtaining quite a low resistivity epitaxial SiGe:B layer. This may particularly be advantageous when the epitaxial SiGe:B layer is used for the formation of source/drain regions. By low resistivity, it is meant epitaxial layers having resistivity values of 0.2 mOhm.cm or lower.

In some embodiments, the flow rate of the p-type dopant precursor may be set to 150 sccm. This may advantageously allow for obtaining quite a high active career concentration in the epitaxial layer. This may also be particularly advantageous when the epitaxial SiGe:B layer is used for the formation of source/drain regions. However, it is to be noted that as the flow rate goes above 200 sccm, resistivity may be degraded and no improvement in active dopant concentration occurs at such high flow rates.

It is to be noted that the flow rate of the p-type dopant precursor may be set to values lower than 50 sccm. However, this may jeopardize the active dopant concentration, such as for example obtaining a very low active dopant concentration.

We now return to FIG. 7(b) showing change of resistivity of Si-containing layer (SiGe:B) as a function boron containing precursor (B₂H₆) flow. In these experiments, temperature of the process is maintained at about 270° C. and the process gas further comprises di-chlorosilane. The epitaxial growth is done on a Si (001) surface.

It is observed in FIG. 7(b) that both for the deposition only case and for case including etching, the resistivity shows a decrease until about a flow of 50 sccm B₂H₆, whereas the resistivity starts to increase for flow rate values higher than 50 sccm. However, at a flow rate of 50 sccm, a very low resistivity is obtained both for deposition only case and for selective process that includes etching as well.

FIG. 8 shows variation of etched thickness of the SiGe:B epitaxial layer as a function of diborane precursor flow when SiI₂H₂ flowrate is taken 100 sccm and 300 sccm. It is observed from the graph that the thickness etched increases as diborane flow is increased when SiI₂H₂ flowrate is 100 sccm. This may infer that addition of SiI₂H₂ may help to incorporate increased amount of boron to the epitaxial layer, and this may consequently lead to an increase in etched thickness. On the other hand, at a diborane flow rate of 50 sccm, the etched thickness obtained with a flowrate of 300 sccm of SiI₂H₂ is higher than that obtained when the SiI₂H₂ flowrate is 100 sccm. This may infer that upon increase in the diborane flow rate, growth rate of the SiGe:B epitaxial layer may increase. Addition of SiI₂H₂ precursor to the process gas may advantageously help to increase the etch rate thus, the etched thickness.

In embodiments, the chlorosilane precursor may be di-chlorosilane and it may be provided at a flow rate in a range of 200 sccm to 400 sccm. In these embodiments, the silicon halide precursor may be provided at a flow rate in a range of 100 sccm to 300 sccm.

In some embodiments, the flow rate of the di-chlorosilane precursor may be from at least 200 sccm to at most 225 sccm, or from at least 225 sccm to at most 250 sccm, or from at least 250 sccm to at most 275 sccm, or from at least 275 sccm to at most 300 sccm, or from at least 300 sccm to at most 325 sccm, or from at least 325 sccm to at most 350 sccm, or from at least 350 sccm to at most 375 sccm, or from at least 375 sccm to at most 400 sccm.

In some embodiments, the flow rate of the silicon halide precursor may be from at least 100 sccm to at most 150 sccm, or from at least 150 sccm to at most 200 sccm, or from at least 200 sccm to at most 250 sccm, or from at least 250 sccm to at most 300 sccm.

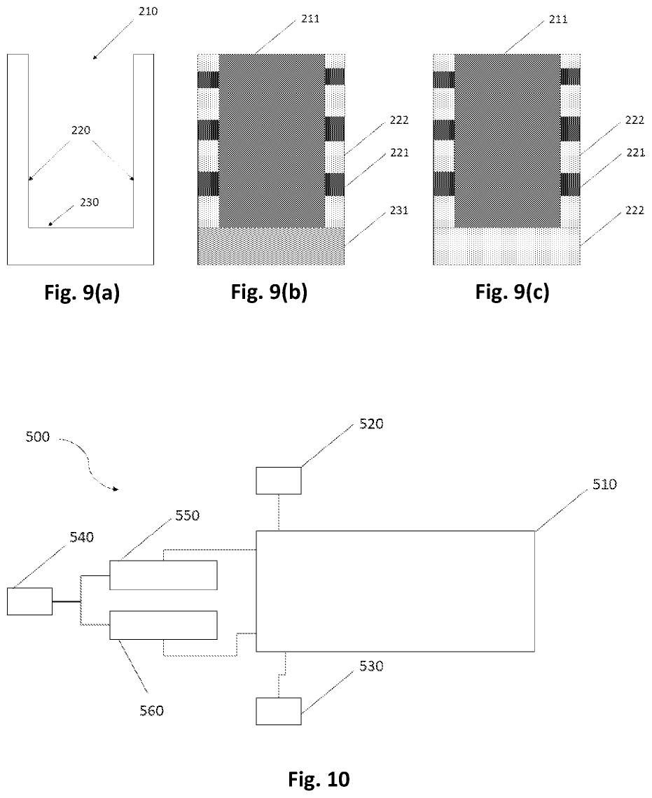

We now return to FIG. 9(a) showing a schematic representation of a gap (210) that may be comprised in the substrate and FIG. 9(b) and FIG. 9(c) showing a schematic representation after the gap is filled.

In embodiments, the epitaxial layer may be formed in a gap (210) comprised in the substrate. The gap may comprise a bottom surface (230) and sidewalls (220) bounding the bottom surface. The bottom surface (230) may comprise the first exposed surface (141) and the sidewalls (220) may comprise the second exposed surface (142).

Thus, the method disclosed in the present disclosure may be used to fill the gap (210) with the epitaxial layer (211) and may advantageously allow for a selective bottom-up filling of the gap (210). This may advantageously allow for forming the epitaxial layer (211) with reduced defects, defects being such as for example seams and voids.

The gap may be used for making a trench, a via or source/drain regions in semiconductor devices. The ratio of the height to width of the gap may be referred to as aspect ratio and this ratio may change depending on the purpose of the gap to be used. While some gaps may be high-aspect ratio gaps, such as for example having an aspect ratio >10, some may be a low aspect ratio gaps, such as for example having an aspect ratio <10.

In some embodiments, as schematized in FIG. 9(b), the bottom surface (230) may consist of a Si {100} facet (231) and the sidewalls (220) may comprise of an oxide (222). The oxide may, in embodiments, be silicon oxide. The silicon oxide may, in some embodiments, be silicon dioxide. The sidewalls (220) may further comprise a high order Si facet (221). In some embodiments, the high order Si facet may be Si {110}.

Thanks to the selective epitaxial growth of the SiGe:B layer according to embodiments of the first aspect of the present disclosure, a bottom-up filling (211) of the gap (210) may be obtained. The provision of the etching gas may enable removal of the layer that may be grown to a lesser extent on the sidewalls (220), thereby facilitating further the bottom-up growth of the epitaxial layer, thereby filling gap with the layer (211).

In some embodiments, as schematized in FIG. 9(c), the bottom surface (230) may consist of an oxide (222) and the sidewalls (220) may also comprise the oxide (222). The oxide may, in embodiments, be silicon oxide. The silicon oxide may, in some embodiments, be silicon dioxide. The sidewalls (220) may further comprise a high order Si facet (221). In some embodiments, the high order Si facet may be Si {110}.

Thanks to the selective epitaxial growth of the SiGe:B layer according to embodiments of the first aspect of the present disclosure, filling (211) of the gap (210) may be obtained by enabling the growth to start from the sidewalls. The provision of the etching gas may enable removal of the layer that may be grown to a lesser extent on the bottom surface (230).

It is to be noted that the flow rate values disclosed with respect to the Si-containing precursor, Ge-containing precursor and p-type dopant precursor may refer to the flow rate values including dilution using H₂ gas. These precursors are the provided to the process chamber further on with the help of the carrier gas.

In embodiments, the flow rate with respect to the Ge-containing precursor may include 5% volume to 10% volume Ge-containing precursor and 90% volume to 95% volume of H₂ gas.

In embodiments, the flow rate with respect to the p-type dopant precursor may include 1% volume of the p-type dopant precursor and 99% H₂ gas.

In embodiments, the flow rate with respect to di-chlorosilane (DCS) may refer directly to its flowrate in the absence of dilution using H₂ gas.

In a second aspect of the present disclosure a substrate processing apparatus (500) is disclosed. We now refer to FIG. 10.

The substrate processing apparatus (500) may comprise a process chamber (510) constructed and arranged for holding a substrate. In embodiments, the substrate processing apparatus may comprise a plurality of process chambers.

The substrate processing apparatus (500) may further comprise a silicon precursor storage module (550). The silicon precursor storage module (550) may be constructed and arranged for holding a Si-containing precursor. Thus, silicon precursor storage module (550) may comprise the Si-containing precursor. The Si-containing precursor may be di-chlorosilane and a silicon halide precursor comprising at least one of iodine and bromine.

The substrate processing apparatus (500) may further comprise a germanium precursor storage module (560). The germanium precursor storage module (560) may be constructed and arranged for holding a Ge-containing precursor. Thus, germanium precursor storage module (560) may comprise the Ge-containing precursor. The Ge-containing precursor may be germane.

A heater (520) may be comprised in the substrate processing apparatus (500) configured for heating and maintaining process temperature in the process chamber (510). In embodiments, infrared lamps may be positioned outside the process chamber and may thus, be used to heat the process chamber by shining light through the walls of the process chamber and to heat the susceptor on which the substrate is positioned, which in turn may heat the substrate. Furthermore, a pressure controller (530) may be comprised in the substrate processing apparatus (500) for attaining and maintaining process pressure in the process chamber (510).

A controller (540) may be operably connected to the silicon precursor storage module (550) and to the germanium precursor storage module (560). The controller (540) may be configured for executing instructions comprised in a non-transitory computer readable medium and may cause the substrate processing apparatus (500) to form the epitaxial layer on the substrate in accordance with embodiments of the first aspect of the present disclosure.

The embodiments of the present disclosure do not limit the scope of invention as these embodiments are defined by the claims appended herein and their legal equivalents. Any equivalent embodiments are intended to be within the scope of this invention. Modifications of the disclosure that are different from one another, in addition to those disclosed herein, may become apparent to those skilled in the art. Such modifications and the embodiments originating therefrom, are also intended to fall within the scope of the claims appended herein.

1. A method for forming a Si-comprising epitaxial layer selectively on a substrate, the method comprising:
providing a substrate to a process chamber, the substrate comprising an exposed surface, the exposed surface comprising a first exposed surface and a second exposed surface, the second exposed surface being different than the first exposed surface,
providing, to the process chamber, a Si-containing precursor, thereby forming a Si-comprising epitaxial layer on the exposed surface, the epitaxial layer comprising a first portion formed on the first exposed surface and a second portion formed on the second exposed surface,
providing an etching gas to the process chamber, thereby removing, selectively, the first portion or the second portion of the epitaxial layer,
wherein the Si-containing precursor is a silicon halide precursor comprising at least one of iodine and bromine.

2. The method according to claim 1, wherein the first exposed surface and the second exposed surface is a single crystalline surface, the second exposed surface having a different crystal orientation than the first exposed surface.

3. The method according to claim 1, wherein the first exposed surface consists of a Si {100}crystal facet and the second exposed surface consists of a Si {110} crystal facet.

4. The method according to claim 1, wherein the epitaxial layer is formed in a gap comprised in the substrate, the gap comprising a bottom surface and sidewalls bounding the bottom surface, wherein the bottom surface comprises the first exposed surface and the sidewalls comprise the second exposed surface.

5. The method according to claim 1, wherein the silicon halide precursor is provided, to the process chamber, substantially simultaneously with a process gas comprising at least a Ge-containing precursor and a p-type dopant precursor, thereby forming a p-type doped SiGe epitaxial layer.

6. The method according to claim 5, wherein the process chamber is maintained, during the selective formation of the epitaxial layer, at a temperature less than 450° C. and at a pressure in a range of 10 Torr to 80 Torr.

7. The method according to claim 5, wherein the silicon halide precursor is provided at a flow rate in a range of 50 sccm-1000 sccm.

8. The method according to claim 5, wherein the Ge-containing precursor is provided at a flow rate in a range of 100 sccm-800 sccm.

9. The method according to claim 5, wherein the p-type dopant precursor is provided at a flow rate in a range of 1 sccm-150 sccm.

10. The method according to claim 5, wherein the process gas comprises substantially of a Ge-containing precursor, and a p-type dopant precursor, thereby forming the p-type doped SiGe epitaxial layer.

11. The method according to claim 10, wherein the process chamber is maintained, during the selective formation of the epitaxial layer, at a temperature of about 400° C., and at a pressure of about 20 Torr.

12. The method according to claim 10, wherein the p-type dopant precursor is provided at a flow rate in a range of 1 sccm-3 sccm.

13. The method according to claim 5, wherein the process gas further comprises a chlorosilane precursor, thereby forming the p-type doped SiGe epitaxial layer.

14. The method according to claim 13, wherein the process chamber is maintained, during the selective formation of the epitaxial layer, at a temperature in a range of 250° C. to 300° C., and at a pressure in a range of 10 Torr to 60 Torr.

15. The method according to claim 14, wherein the process chamber is maintained, during the selective formation of the epitaxial layer, at a temperature of about 270° C.

16. The method according to claim 14, wherein the p-type dopant precursor is provided at a flow rate in a range of 25 sccm-200 sccm.

17. The method according to claim 13, wherein the chlorosilane precursor is di-chlorosilane and is provided at a flow rate in a range of 200 sccm to 400 sccm and wherein the silicon halide precursor is provided at a flow rate in a range of 100 sccm to 300 sccm.

18. The method according to claim 5, wherein the p-type dopant precursor is diborane and the Ge-containing precursor is germane.

19. A substrate processing apparatus for forming a Si-comprising epitaxial layer selectively on a substrate, the apparatus comprising:
a process chamber constructed and arranged for holding a substrate,
a silicon precursor storage module comprising di-chlorosilane and a silicon halide precursor comprising at least one of iodine and bromine,
a germanium precursor storage module comprising germane,
a heater configured for heating and maintaining process temperature in the process chamber, a pressure controller configured for attaining and maintaining process pressure in the process chamber, and
a controller operably connected to the silicon precursor storage module and to the germanium precursor storage module and configured for executing instructions comprised in a non-transitory computer readable medium, and to cause the substrate processing apparatus to form the epitaxial layer on the substrate in accordance with a method comprising
providing a substrate to a process chamber, the substrate comprising an exposed surface, the exposed surface comprising a first exposed surface and a second exposed surface, the second exposed surface being different than the first exposed surface,
providing, to the process chamber, a Si-containing precursor, thereby forming a Si-comprising epitaxial layer on the exposed surface, the epitaxial layer comprising a first portion formed on the first exposed surface and a second portion formed on the second exposed surface,
providing an etching gas to the process chamber, thereby removing, selectively, the first portion or the second portion of the epitaxial layer,
wherein the Si-containing precursor is a silicon halide precursor comprising at least one of iodine and bromine.
